(19) United States
(12) Patent Application Publication
(10) Pub. No.: US 2025/0294877 A1
(43) Pub. Date: Sep. 18, 2025

(54) ISOLATION STRUCTURE FOR MULTI-VOLTAGE INTEGRATED CIRCUIT

(71) Applicant: GlobalFoundries U.S. Inc., Malta, NY (US)

(72) Inventors: Navneet K. Jain, Milpitas, CA (US); Mahbub Rashed, Cupertino, CA (US)

(21) Appl. No.: 18/604,947

(22) Filed: Mar. 14, 2024

(51) Int. Cl. H01L 27/12

(52) U.S. Cl. CPC H10D 86/201

(57) ABSTRACT

Disclosed are embodiments of an integrated circuit (IC) including a first IC section operating in a first voltage domain, a second IC section operating in a second voltage domain, and an isolation structure between the two sections. The isolation structure can include a trench isolation region within a semiconductor layer, isolating first PFETs and, optionally, isolating second PFETs. The isolating first PFETs can be series-connected and can include a first portion of the semiconductor layer between a functional PFET of the first IC section and a first edge of the trench isolation region. Additionally, the isolating first PFETs can operate in the first voltage domain and can be biased so as to remain always off. The isolating second PFETs can be similarly configured between a functional PFET of the second IC section and a second edge of the trench isolation region opposite the first edge.

### BACKGROUND

The present disclosure relates to integrated circuits (IC) and, more particularly, to embodiments of a multi-voltage IC with an improved isolation structure between different voltage domains.

Trench isolation structures (e.g., shallow trench isolation (STI) structures or deep trench isolation (DTI) structures) have historically been used to electrically isolate one active device region in a semiconductor layer from another. In semiconductor-on-insulator processing technology platforms designs have been developed in which transistors (as opposed to trench isolation structures) are used to electrically isolate one active device region from another. Specifically, an isolating transistor can be formed using a portion of a semiconductor layer between two active devices regions. Terminals of the isolating transistor can be appropriately biased in an attempt to continuously maintain the isolating transistor in an off state (i.e., to be always off), thereby preventing electric current from passing between the two active device regions. One advantage of using isolating transistors is that they can be relatively small in size as compared to trench isolation structures and, thus, they can facilitate IC size scaling. However, in multi-voltage ICs (i.e., IC that have circuit components operating in multiple different voltage domains) these isolating transistors may exhibit significant leakage current. This leakage current can result in undesirable shorting between active device regions.

### SUMMARY

Disclosed herein are embodiments of a multi-voltage integrated circuit (IC) structure. In the disclosed embodiments, the IC structure can include a semiconductor body. The IC structure can further include an isolation structure. The isolation structure can include a trench isolation region, which extends through the semiconductor body to an insulator layer and which has a first edge and a second edge opposite the first edge. The isolation structure can further include multiple isolating first transistors connected in series on a first portion of the semiconductor body adjacent to the first edge of the trench isolation region. These isolating first transistors can further be connected to receive a supply voltage so that they are maintained in an off state.

More specifically, disclosed herein are embodiments of an IC structure. The IC structure can include a semiconductor body. The IC structure can further include an isolation structure. The isolation structure can include a trench isolation region, which extends through the semiconductor body to an insulator layer and which has a first edge and a second edge opposite the first edge. The isolation structure can further include multiple isolating first transistors connected in series on a first portion of the semiconductor body adjacent to the first edge of the trench isolation region. The isolating first transistors can be P-channel field effect transistors (PFETs) and appropriately biased by a first positive supply voltage so as to be maintained in an off state. For example, in some embodiments, a first source region in the first portion proximal to the first edge and all first gates of the isolating first transistors can be electrically connected to the same first bias voltage node. The first bias voltage node can be connected to receive the first positive supply voltage to maintain the isolating first transistors in the off state. In other embodiments, each isolating first transistor can have a first source region and a first gate connected to a corresponding first bias voltage node. Each first bias voltage node can be connected to receive the same first positive supply voltage to maintain the isolating first transistors in the off-state.

Other embodiments of an IC structure disclosed herein can include a semiconductor body. The IC structure can further include an isolation structure. The isolation structure can include a trench isolation region, which extends through the semiconductor body to an insulator layer and which has a first edge and a second edge opposite the first edge. The isolation structure can further include both isolating first PFETs and isolating second PFETs. The isolating first PFETs can be connected in series on a first portion of the semiconductor body adjacent to the first edge of the trench isolation region. At least a first source region in the first portion of the semiconductor body proximal to the first edge and all first gates of the isolating first PFETs can be connected to at least one first bias voltage node. The at least one first bias voltage node can be connected so as to receive a first positive supply voltage in order to maintain the isolating first PFETs in an off state. The isolating second PFETs can be connected in series on a second portion of the semiconductor body adjacent to the second edge of the trench isolation region. At least one second source region in the second portion of the semiconductor body adjacent to the second edge and all second gates of the isolating second PFETs can be connected to at least one second bias voltage node. The at least one second bias voltage node can be connected so as to receive a second positive supply voltage to maintain the isolating second PFETs in the off state. In these embodiment, the second positive supply voltage can specifically be different from the first positive supply voltage.

It should be noted that all aspects, examples, and features of disclosed embodiments mentioned in the summary above can be combined in any technically possible way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIGS. 1A, 1B, and 1C are a schematic drawing, a layout drawing, and a cross-section drawing, respectively, illustrating an embodiment of a multi-voltage IC structure;

FIGS. 2-4 are schematic drawings a layout drawing, and a cross-section drawing, respectively, illustrating alternative embodiments of a multi-voltage IC structure;

FIG. 5A is a graph illustrating, for an example PFET design, a decrease in saturation threshold voltage with an increase in the amount of source/drain side semiconductor material; and

FIG. 5B is a graph illustrating, for the example PFET design, an increase in saturation drain current with an increase in the amount of source/drain side semiconductor material.

### DETAILED DESCRIPTION

As mentioned above, in semiconductor-on-insulator processing technology platforms, designs have been developed in which transistors (as opposed to trench isolation structures) are used to electrically isolate one active device region from another. Specifically, an isolating transistor can be formed using a portion of a semiconductor layer between two active devices regions. Terminals of the isolating transistor can be electrically biased at appropriate levels to continuously maintained the isolating transistor in an off state (i.e., to be always off), thereby preventing electric current from passing between the two active device regions. One advantage of using isolating transistors is that they can be relatively small in size as compared to trench isolation structures and, thus, they can facilitate IC size scaling. However, in multi-voltage ICs (i.e., IC that have circuit components operating in multiple different voltage domains) these isolating transistors may exhibit significant leakage current. This leakage current can result in undesirable shorting between active device regions.

For example, consider a P-channel field effect transistor (PFET) configured as an isolating PFET. The isolating PFET can include, within a semiconductor layer above an insulator layer, a channel region positioned laterally between a source region and a drain region. The isolating PFET can further include a gate on the semiconductor layer adjacent to the channel region. The drain region of the isolating PFET can abut a source/drain region of an adjacent functional PFET. The source region and the gate of the isolating PFET can be continuously tied to a positive supply voltage (VDD). Thus, the isolating PFET should always be in an off state (i.e., non-conductive), thereby preventing current flow from the functional PFET through the isolating PFET. However, if the isolating PFET operates in one voltage domain and the adjacent functional PFET operates in a different voltage domain, then the voltage conditions on the terminals of the isolating PFET will dictate whether or not leakage current will flow therethrough. If the drain voltage (Vd) of the isolating PFET is at a higher voltage level than its gate voltage (Vg) (which is at VDD), leakage will occur. Additionally, if conditions are such that Vg of the isolating PFET is left floating, then the amount of leakage will be unpredictable. If conditions are such that Vg of the isolating PFET switches to ground (VSS) (e.g., in the case of some level shifters), then the amount of leakage and the ohmic drop (IR drop) would be significant.

In view of the foregoing, disclosed herein are embodiments of a multi-voltage IC including an improved isolation structure (e.g., a zero-leakage isolation structure) between different voltage domains. The isolation structure can include a trench isolation region that divides an elongated planar semiconductor for inclusion in different IC sections that operate in different voltage domains. The isolation structure can also include isolating first transistors (e.g., isolating P-channel field effect transistors (PFETs)) on a first portion of the semiconductor body between a functional first transistor (e.g., a functional PFET) in the first IC section and a first edge of the trench isolation region. The isolating first PFETs can operate in the first voltage domain and can specifically be biased so as to be maintained in an always off state. Optionally, the isolation structure can also include isolating second transistors (e.g., also isolating PFETs). The isolating second PFETs can be on a second portion of the semiconductor layer between a functional second transistor (e.g., another functional PFET) in the second IC section and a second edge of the trench isolation region opposite the first edge. The isolating second PFETs can operate in the second voltage domain and can specifically be biased so as to be maintained in an always off state. Such an isolation structure prevents cross-voltage leakage between the different voltage domains and also enhances functional PFET performance (e.g., reduces saturation threshold voltage (VTsat) and increases saturation drain current (Idsat)). Specifically, the combination of the trench isolation region and the isolating PFETs prevent cross-voltage leakage. Additionally, due to the presence of the isolating PFETs between a functional PFET and an edge of the trench isolation region, a relatively large amount (e.g., greater than 200 nm) of semiconductor material separates the channel region of the functional PFET from the trench isolation region. As a result, strain on the channel region of the functional PFET is increased, so VTsat is reduced and Idsat increases.

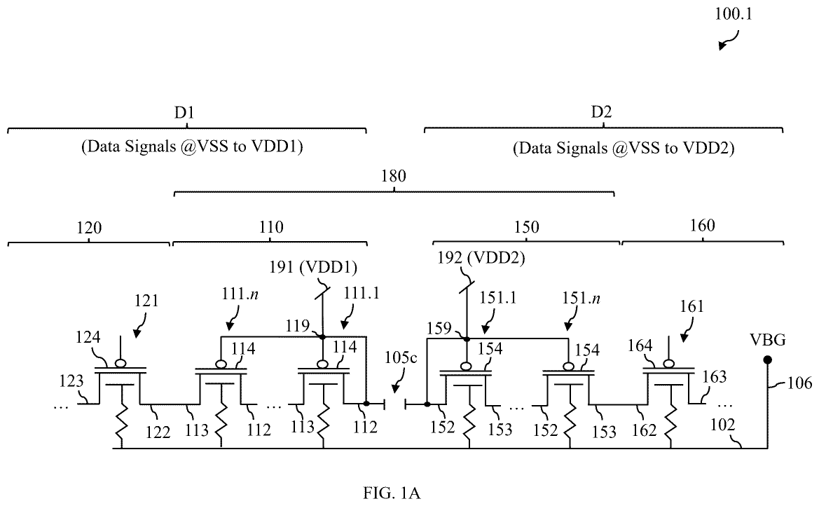

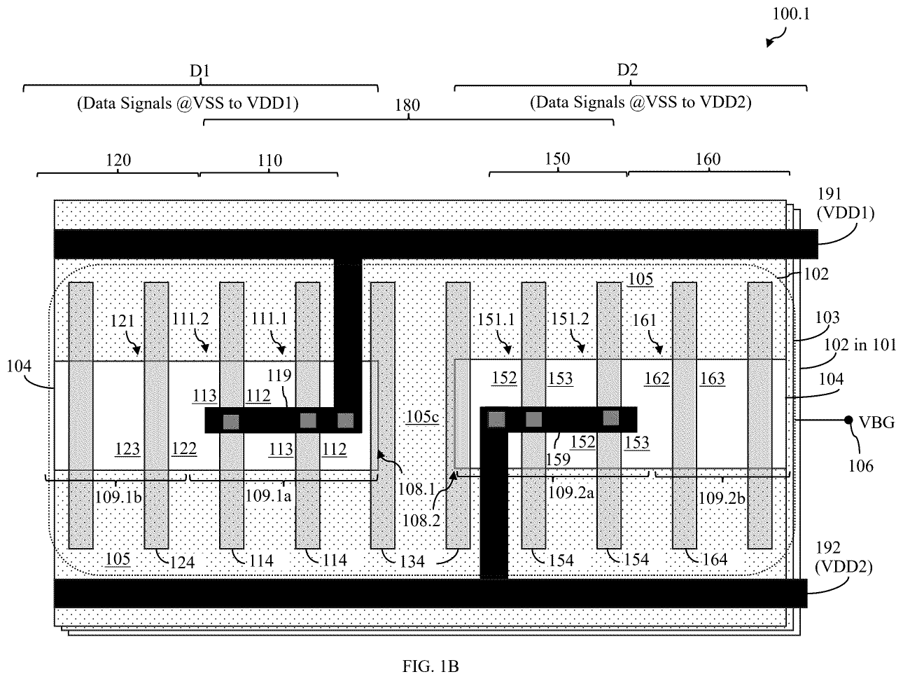

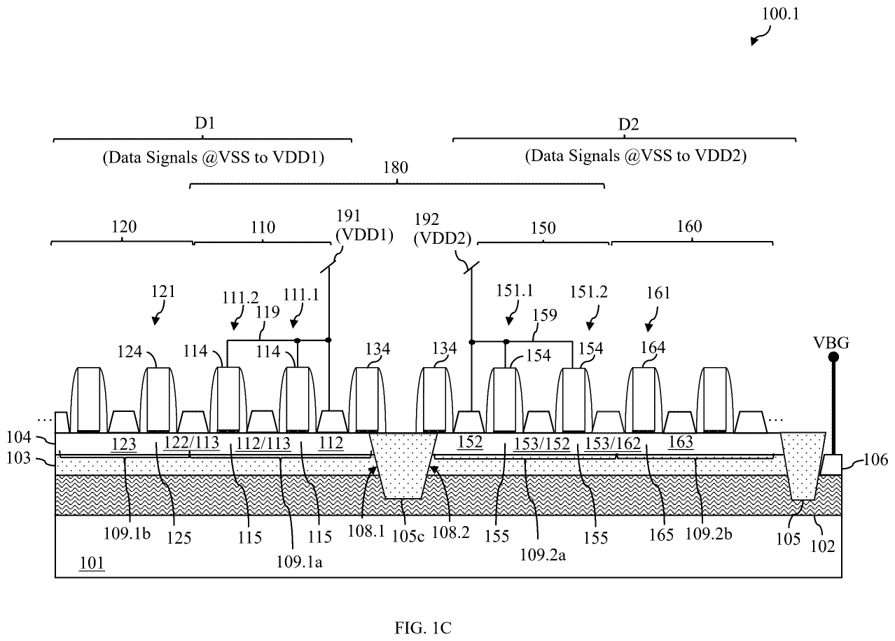

More particularly, FIGS. 1A, 1B, and 1C are a schematic drawing, a layout drawing, and a cross-section drawing, respectively, illustrating an embodiment of a multi-voltage IC structure 100.1. IC structure 100.1 can be implemented in a semiconductor-on-insulator processing technology platform. For purposes of illustration, IC structure 100.1 is illustrated in FIGS. 1A-1C as being implemented in a fully depleted semiconductor-on-insulator (e.g., a fully depleted silicon-on-insulator (FDSOI)) processing technology platform.

IC structure 100.1 can include a semiconductor substrate 101. Semiconductor substrate 101 can be, for example, a monocrystalline silicon substrate or a substrate of any other suitable monocrystalline semiconductor material (e.g., silicon germanium, etc.). IC structure 100.1 can further include an insulator layer 103 on semiconductor substrate 101. Insulator layer 103 can be, for example, a silicon dioxide layer or a layer of any other suitable insulator material. IC structure 100.1 can further include a semiconductor layer on insulator layer 103. The semiconductor layer can be, for example, a monocrystalline silicon layer or a layer of any other suitable monocrystalline semiconductor material (e.g., silicon germanium, etc.).

IC structure 100.1 can include different sections (e.g., a first IC section 120 and a second IC section 160) that operate in different voltage domains (e.g., a first voltage domain (D1) and a second voltage domain (D2)). Specifically, the first IC section 120 can be supplied with a first positive supply voltage at a first positive supply voltage level (VDD1). Additionally, any first data signals within the first IC section 120 can swing between a first minimum low voltage level (e.g., at ground (VSS)) and a first maximum voltage level that is no greater than VDD1. The second IC section 160 can be supplied with a second positive supply voltage at a second positive supply voltage level (VDD2), which is different from VDD1. Additionally, any second data signals within the second IC section 160 can swing between a second minimum low voltage level (e.g., at ground (VSS)) and a second maximum voltage level that is no greater than VDD2.

IC structure 100.1 can further include an isolation structure 180 between functional first and second transistors 121 and 161 in first IC section 120 and second IC section 160, respectively. Isolation structure 180 can include a trench isolation region 105c, multiple series-connected isolating first transistors 111.1-111.n adjacent to a first edge 108.1 of trench isolation region 105c and, optionally, multiple series-connected isolating second transistors 151.1-151.n adjacent to a second edge 108.2 of trench isolation region 105c. For purposes of illustration, two isolating first transistors 111.1-111.2 and two isolating second transistors 151.1-151.2 are shown in the figures. However, it should be understood that the figures are not intended to be limiting. For example, isolation structure 180 could include any number n of two or more isolating transistors on at least one and, optionally, both sides of the trench isolation region 105c. As discussed in greater detail below, functional first transistor 121, functional second transistor 161, isolating first transistors 111.1-111.n and isolating second transistors 151.1-151.n can each be P-channel field effect transistors (PFETs).

More particularly, the semiconductor layer can be patterned to include an elongated planar semiconductor body 104 for a row of PFETs. This row of PFETs can include isolating first PFETs 111.1-111.2 of isolation structure 180, functional first PFET 121 of first IC section 120, isolating second PFETs 151.1-151.2 of isolation structure 180, and functional second PFET 161 of second IC section 160. The elongated planar semiconductor body 104 can have a shape defined within the semiconductor layer by trench isolation regions 105. Trench isolation regions 105 can be, for example, shallow trench isolation (STI) regions on opposing sides of the elongated planar semiconductor body 104 so as to define the width thereof. STI regions include trenches, which extend downward from the top surface of semiconductor layer to and, optionally, into or completely through insulator layer 103. STI regions can further include one or more layers of isolation material (e.g., silicon dioxide, silicon nitride, silicon oxynitride, or any other suitable isolation material) filling the trenches.

Isolation structure 180 can include an additional trench isolation region 105c (e.g., an additional STI region), which extends laterally between STI regions 105 from one side of planar elongated semiconductor body 104 to the other and which further extends vertically at least to insulator layer 103, thereby dividing the elongated planar semiconductor body 104 into discrete sections for the first voltage domain (D1) and the second voltage domain (D2), respectively.

Isolation structure 180 can further include multiple isolating first PFETs 111.1-111.2 adjacent first edge 108.1 of trench isolation region 105c and, optionally, multiple isolating second PFETs 151.1-151.2 adjacent to a second edge 108.2 of trench isolation region 105c opposite first edge 108.2.

Isolating first PFETs 111.1-111.2 can be on a first portion 109.1a of the elongated planar semiconductor body 104 positioned laterally immediately adjacent to the first edge 108.1 of trench isolation region 105c. Each isolating first PFET 111.1-111.2 can include, within first portion 109.1a, a first source region 112, a first drain region 113, and a first channel region 115 positioned laterally between first source region 112 and first drain region 113. As illustrated, source/drain regions of immediately adjacent isolating first PFETs 111.1-111.2 can be shared (i.e., can be side by side within the same area of the semiconductor body). Optionally, each isolating first PFET 111.1-111.2 can include a raised first source region and a raised first drain region on the top surface of the first portion 109.1a adjacent to the first source region 112 and the first drain region 113, respectively. The raised source/drain regions can be in situ doped epitaxial semiconductor layers. Each isolating first PFET 111.1-111.2 can further include a first gate 114 on the top surface of first portion 109.1a adjacent to the first channel region 115 and electrically isolated from the adjacent source/drain regions by gate sidewall spacers.

One or more functional first PFETs of the first IC section 120 of IC structure 100.1 can be formed on a remaining portion 109.1b of elongated planar semiconductor body 104 on the same first side of trench isolation region 105c. That is, elongated planar semiconductor body 104 can include an additional first portion 109.1b separated from first edge 108.1 of trench isolation region 105c by first portion 109.1a. A functional first PFET 121 of first IC section 120 can include an additional first channel region 125 within additional first portion 109.1b positioned laterally between an additional first source region 122 and an additional first drain region 123. Optionally, each functional first PFET 121 can further include raised source/drain regions (e.g., in situ doped epitaxial semiconductor layers) on the additional first source region 122 and additional first drain region 123. An additional first gate 124 with gate sidewall spacers can be on the top surface of additional first portion 109.1b adjacent to additional first channel region 125. As illustrated, the additional first source region 122 of this functional first PFET 121 and the first drain region 113 of the nth isolating first PFET (e.g., isolating first PFET 111.2) (which is in the first portion 109.1a distal to the first edge 108.1) can be shared. That is, the additional first source region 122 of the functional first PFET 121 is side by side with (i.e., abuts) the first drain region 113 of the nth isolating first PFET.

As mentioned above, first IC section 120 can operate in first voltage domain (D1). That is, it can be supplied with a first positive supply voltage at a first positive supply voltage level (VDD1). Additionally, any first data signals within first IC section 120 can swing between a first minimum low voltage level (e.g., at ground (VSS)) and a first maximum voltage level that is no greater than VDD1. Thus, the voltage level on the first drain region 113 of the nth isolating first PFET (e.g., isolating first PFET 111.2, as illustrated), which abuts the additional first source region 122 of the functional first PFET 121, is connectable to receive a first data signal that swings between VSS and VDD1 and, particularly, that is no greater than VDD1. In this example, first source region 112 of the initial isolating first PFET 111.1 in the first portion 109.1a proximal to the first edge 108.1 as well as all first gates 114 can be electrically connected to a first bias voltage node 119 and the first bias voltage node 119 can be electrically connected to the first positive supply voltage rail 191 for receiving VDD1. As a result, all isolating first PFETs are maintained in an off state (i.e., remain non-conductive). Specifically, the voltage level on the first gates 114 will never be less than the voltage level at the first drain region 113 of the nth isolating PFET (e.g., isolating first PFET 111.2, as illustrated) so all isolating first PFETs will remain continuously off.

Isolating second PFETs 151.1-151.2 can be on a second portion 109.2a of the elongated planar semiconductor body 104 positioned laterally immediately adjacent to the second edge 108.2 of trench isolation region 105c. Each isolating second PFET 151.1-151.2 can include, within second portion 109.2a, a second source region 152, a second drain region 153, and a second channel region 155 positioned laterally between second source region 152 and second drain region 153. As illustrated, source/drain regions of immediately adjacent isolating second PFETs 151.1-151.2 can be shared (i.e., can be side by side within the same area of the semiconductor body). Optionally, each isolating second PFET 151.1-151.2 can include a raised second source region and a raised second drain region on the top surface of the second portion 109.2a adjacent to the second source region 152 and the second drain region 153, respectively. The raised source/drain regions can be in situ doped epitaxial semiconductor layers. Each isolating second PFET 151.1-151.2 can further include a second gate 154 on the top surface of second portion 109.2a adjacent to the second channel region 155 and electrically isolated from the adjacent source/drain regions by gate sidewall spacers.

One or more functional second PFETs of the second IC section 160 of IC structure 100.1 can be formed on a remaining portion 109.2b of elongated planar semiconductor body 104 on the same second side of trench isolation region 105c. That is, elongated planar semiconductor body 104 can include an additional second portion 109.2b separated from second edge 108.2 of trench isolation region 105c by second portion 109.2a. A functional second PFET 161 of second IC section 160 can include an additional second channel region 165 within additional second portion 109.2b positioned laterally between an additional second source region 162 and an additional second drain region 163. Optionally, each functional second PFET 161 can further include raised source/drain regions (e.g., in situ doped epitaxial semiconductor layers) on the additional second source region 162 and additional second drain region 163. An additional second gate 164 with gate sidewall spacers can be on the top surface of additional second portion 109.2b adjacent to additional second channel region 165. As illustrated, the additional second source region 162 of this functional second PFET 161 and the second drain region 153 of the nth isolating second PFET (e.g., isolating second PFET 151.2) (which is in the second portion 109.2a distal to the second edge 108.2) can be shared. That is, the additional second source region 162 of the functional second PFET 161 is side by side with (i.e., abuts) the additional second drain region 163 of the nth isolating second PFET.

As mentioned above, second IC section 160 can operate in second voltage domain (D2). That is, it can be supplied with a second positive supply voltage at a second positive supply voltage level (VDD2). Additionally, any second data signals within second IC section 160 can swing between a second minimum low voltage level (e.g., at ground (VSS)) and a second maximum voltage level that is no greater than VDD2. Thus, the voltage level on the additional second drain region 163 of the nth isolating second PFET (e.g., isolating second PFET 151.2, as illustrated), which abuts the additional second source region 162 of the functional second PFET 161, is connectable to receive a second data signal that swings between VSS and VDD2 and, particularly, that is no greater than VDD2. In this case, second source region 152 of the initial isolating second PFET 151.1 in the second portion 109.2a proximal to the second edge 108.2 and all second gates 154 can be electrically connected to a second bias voltage node 159 and the second bias voltage node 159 can be electrically connected to the second positive supply voltage rail 192 for receiving VDD2. As a result, all isolating second PFETs remain in an off state (i.e., remain non-conductive). Specifically, the voltage level on the second gates 154 will never be less than the voltage level at the second drain region 153 of the nth isolating second PFET (e.g., isolating second PFET 151.2, as illustrated) so all isolating second PFETs will remain continuously off.

It should be noted, as illustrated in FIG. 1C, the various gates of the PFETs (e.g., isolating first PFETs 111.1-111.2, functional first PFET 121, isolating second PFETs 151.1-151.2, and functional second PFET 161) can be patterned so that they are parallel across the elongated planar semiconductor body 104 and so that gate pitch is uniform. That is, the distance between center points of each pair of adjacent gates can be essentially the same. In this case, dummy gates 134 (i.e., non-functioning gates) may land on trench isolation region 105c.

In each of the PFETs described above (e.g., isolating first PFETs 111.1-111.2, functional first PFET 121, isolating second PFETs 151.1-151.2, and functional second PFET 161) the source/drain regions can have P-type conductivity at a relatively high conductivity level (e.g., can be P+ source/drain regions) and the channel region can be either intrinsic (i.e., undoped) or can have N-type conductivity at a relatively low conductivity level (e.g., can be an N-channel region). Additionally, the gates of such PFETs can be, for example, gate-first polysilicon gate structures, gate-first high-K metal gate (HKMG) structures, gate-last HKMG structures (also referred to as a replacement metal gate (RMG) structure), or any other suitable type of gate structures. The gates will have opposing sidewalls and gate sidewall spacers positioned laterally adjacent to the opposing sidewalls. The gate sidewall spacers can include one or more layers of isolation material (e.g., of silicon dioxide, silicon oxynitride, silicon nitride, or any other isolation material suitable) for electrically isolating the gates from the adjacent source/drain regions. Gates with gate sidewall spacers as described above are well known in the art and, thus, the details thereof have been omitted from the specification in order to allow the reader to focus on the salient aspects of the disclosed embodiments.

As mentioned above, for purposes of illustration, IC structure 100.1 is illustrated in FIGS. 1A-1C as being implemented in a fully depleted semiconductor-on-insulator (e.g., FDSOI) processing technology platform. One advantage of fully depleted semiconductor-on-insulator (e.g., FDSOI) chip structures is that FETs can be formed on the insulator layer above wells (also referred to herein as well regions) of different conductivity types in order to achieve different threshold voltages (VTs). For purposes of this disclosure, a well region refers to a region of semiconductor material doped (e.g., via a dopant implantation process or any other suitable doping process) so as to have a particular type of conductivity (e.g., N-type conductivity or P-type conductivity). A well region doped so as to have N-type conductivity is referred to herein as an Nwell and a well doped so as to have P-type conductivity is referred to herein as a Pwell. For super low threshold voltage (SLVT) or low threshold voltage (LVT) FETs, NFETs can be formed above Nwells and PFETs can be formed above Pwells. For regular threshold voltage (RVT) or high threshold voltage (HVT) FETs, NFETs can be formed above Pwells and PFETs can be formed above Nwells. Those skilled in the art will recognize that whether the FETs are SLVT or LVT FETs or whether they are RVT or HVT FETs will depend upon the design (e.g., device size, etc.) and process specifications (e.g., dopant concentrations, etc.). Thus, for example, in isolation structure 100.1, a Pwell 102 can be included within semiconductor substrate 101 aligned below the row of PFETs such that the PFETs therein (e.g., isolating first PFETs 111.1-111.2, functional first PFET 121, isolating second PFETs 151.1-151.2, and functional second PFET 161) are SLVT or, alternatively, LVT PFETs.

Another advantage of fully depleted semiconductor-on-insulator (e.g., FDSOI) chip structures is that back biasing (also referred to herein as back gate biasing) can be employed to fine tune the threshold voltages (regardless of whether the FETs are SLVT/LVT or RVT/HVT FETs). Specifically, in this case, the insulator layer 103 and well region 102 below each FET channel region effectively function as a gate dielectric layer and gate conductor layer of a back gate, respectively. Forward back biasing (FBB) refers to applying a back gate bias voltage (VBG) to a back gate (particularly, to a well region below a FET) to reduce VT. Generally, for a PFET, FBB is achieved by applying a negative gate bias voltage (VN) to the well region; whereas, for an NFET, FBB is achieved by applying a positive gate bias voltage (VP) to the well region. Reverse back biasing (RBB) refers specifically to applying a VBG to a back gate (particularly, to a well region below a FET) to increase VT. Generally, for a PFET, RBB is achieved by applying VP to the well region; whereas, for an NFET, RBB is achieved by applying VN to the well region. Alternatively, 0.0V could be applied to the well region for zero-back biasing. Well region 102 biasing can be achieved, for example, via a well tap 106. Those skilled in the art will recognize that fully depleted semiconductor-on-insulator (e.g., FDSOI) chip structures will typically include combinations of semiconductor-on-insulator regions and bulk regions. Bulk regions will be devoid of the semiconductor layer and insulator layer. Well tap 106 can, for example, be located in a bulk region. Well tap 106 can be an epitaxial semiconductor layer on the top surface of semiconductor substrate 101 immediately adjacent to well region 102. Alternatively, well tap 106 can be an additional doped region within well region 102. In either case, well tap 106 can have the same type conductivity as well region 102 at higher conductivity level. For example, for a Pwell, well tap can be a P+ well tap. Well tap 106 can be electrically isolated from any adjacent source/drain regions (e.g., by an STI region) and can further be electrically connected (e.g., via a middle of the line (MOL) contact and back end of the line (BEOL) interconnects) to receive VBG.

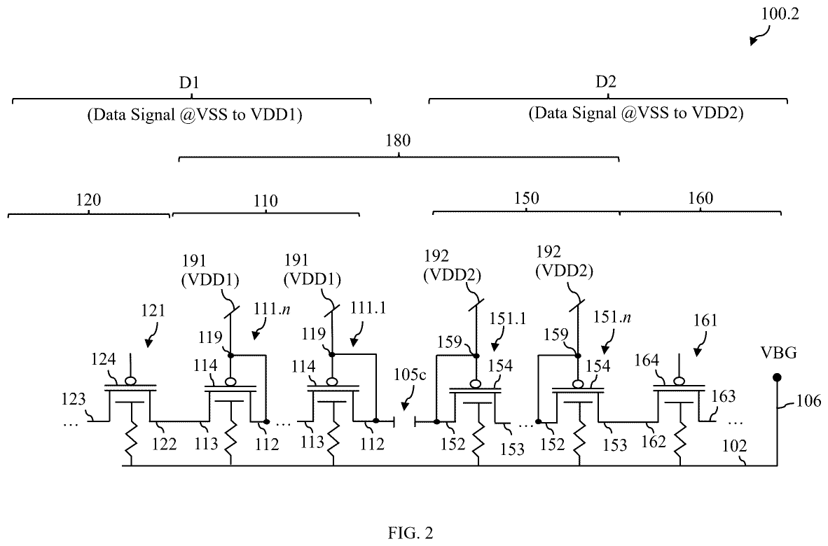

FIG. 2 is a schematic drawing illustrating another embodiment of a multi-voltage IC structure 100.2. IC structure 100.2 can be configured essentially the same as IC structure 100.1, described in detail above, except that: (1) the first gate 114 and first source region 112 of each isolating first PFET (e.g., 111.1-111.n) are electrically connected to a corresponding first bias voltage node 119, which is connected to the first positive supply voltage rail 191 for receiving VDD1; and (2), the second gate 154 and second source region 152 of each isolating second PFET (e.g., 151.1-151.n) are electrically connected to a corresponding second bias voltage node 159, which is connected to the second positive supply voltage rail 192 for receiving VDD2.

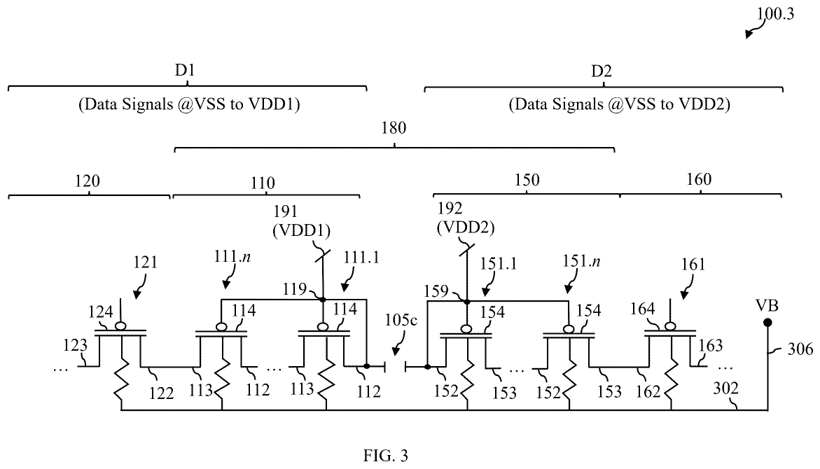

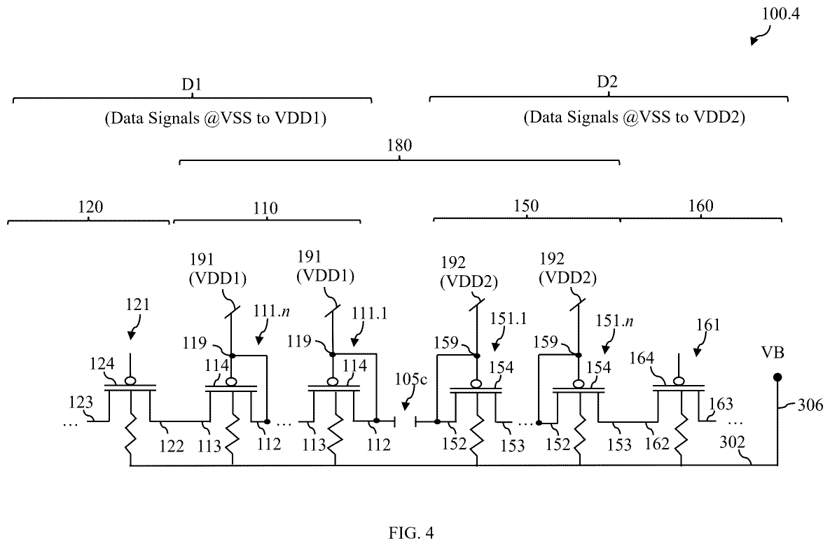

FIGS. 3 and 4 are schematic drawings illustrating still other embodiments of a multi-voltage IC structures 100.3 and 100.4, respectively. IC structures 100.3 and 100.4 can be configured essentially the same as IC structures 100.1 and 100.2, respectively, described in detail above, except that they can be implemented in a partially depleted semiconductor-on-insulator (e.g., a partially depleted silicon-on-insulator (PDSOI)) processing technology platform. In this case, elongated planar semiconductor body 104 will be relatively thick such that the PFETs include body regions 302 (e.g., at the same conductivity type and level as the channel regions) between their active device regions (including their channel, source, and drain regions) and the insulator layer 103. In this case, the body regions of the PFETs can optionally be biased with a body bias voltage (VB) to adjust VT. That is, optionally, IC structures 100.3 and 100.4 can include a body contact region 306. Body contact region 306 can be an additional doped region within the semiconductor body 104. Body contact region 306 can have the same type conductivity as the PFET body regions at a higher conductivity level (e.g., body contact region 306 can be an N+ body contact region). Body contact region 306 can be electrically isolated from any adjacent source/drain regions (e.g., via an STI region) and can further be electrically connected (e.g., via a middle of the line (MOL) contact and back end of the line (BEOL) interconnects) to receive a body bias voltage (VB) for adjusting VT.

In each of the embodiments described above (e.g., IC structure 100.1 of FIGS. 1A-1C, IC structure 100.2 of FIG. 2, IC structure 100.3 of FIG. 3 and IC structure 100.4 of FIG. 4), the isolation structure 180 prevents cross-voltage leakage between D1 and D2 and also enhances functional PFET performance. Specifically, the combination of the trench isolation region and the isolating PFETs prevent cross-voltage leakage. Additionally, due to the presence of isolating first PFETs 111.1-111.n between a functional first PFET 121 and first edge 108.1 of the trench isolation region 105c, a relatively large amount of semiconductor material separates additional first channel region 125 of functional first PFET 121 from the trench isolation region 105c. As a result, strain on additional first channel region 125 of functional first PFET 121 is increased as compared to if the functional first PFET 121 were to have a source/drain region abutting first edge 108.1 of trench isolation region 105c. Thus, VTsat of functional first PFET 121 can be lowered and Idsat of functional first PFET 121 can be increased to levels similar to that of a functional PFET on a continuous semiconductor body (i.e., on a semiconductor body devoid of the trench isolation region 105c). Similarly, presence of isolating second PFETs 151.1-151.n between a functional second PFET 161 and second edge 108.2 of the trench isolation region 105c, a relatively large amount of semiconductor material separates additional second channel region 165 of functional second PFET 161 from the trench isolation region 105c. As a result, strain on additional second channel region 165 of functional second PFET 161 is increased as compared to if the functional second PFET 161 were to have a source/drain region abutting second edge 108.2 of trench isolation region 105c. Thus, VTsat of functional second PFET 161 can be lowered and Idsat of functional second PFET 161 can be increased to levels similar to that of a functional PFET on a continuous semiconductor body (i.e., on a semiconductor body devoid of the trench isolation region 105c).

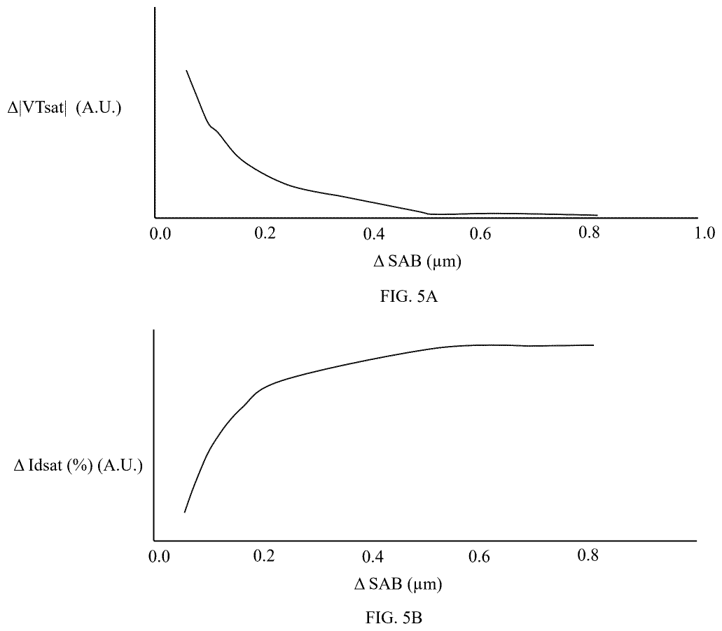

In the isolation structure 180, with each additional isolating PFET between a functional PFET and an edge of the trench isolation region 105c, the distance between the gate of the functional PFET and the edge of the trench isolation region 105c increases by an amount equal to the gate pitch. FIG. 5A is a graph illustrating, for an example SLVT functional PFET design, the reduction in the absolute value of VTsat that can be exhibited as the amount of semiconductor material on one source/drain side of the functional PFET increases (i.e., as the distance between the gate of the functional PFET and the edge of the trench isolation region increases). FIG. 5B is a graph illustrating, for the example SLVT functional PFET design, the increase Idsat that can be exhibited as the amount of semiconductor material on one source/drain side of the functional PFET increases (i.e., as the distance between the gate of the functional PFET and the edge of the trench isolation region increases).

Techniques for various components of the IC structures disclosed herein and described above (e.g., PFETs, trench isolation regions, interconnects, etc.) in either fully depleted semiconductor-on-insulator (e.g., FDSOI) or partially depleted semiconductor-on-insulator (e.g., PDSOI) processing technology platforms are known in the art. Thus, the details thereof have been omitted from this specification in order to allow the reader to focus on the salient aspects of the disclosed embodiments related specifically to the configuration of the isolation structure 180 (as described in detail above including a trench isolation region 105c, first isolating PFETs 111.1-111.n, and optionally second isolating PFETs 151.1-151.n) between two different voltage domains (e.g., to substantially reduce leakage or achieve zero-leakage).

It should be understood that in the method and structures described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an,” and “the” are intended to include the plural forms as well, unless the context clearly indicates otherwise. Additionally, as used herein, the terms “comprises,” “comprising,” “includes,” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a semiconductor body; and
an isolation structure including:
a trench isolation region extending through the semiconductor body to an insulator layer, wherein the trench isolation region has a first edge and a second edge opposite the first edge; and
isolating first transistors connected in series on a first portion of the semiconductor body adjacent to the first edge, wherein the isolating first transistors are connected to receive a supply voltage to maintain the isolating first transistors an off state.

2. The structure of claim 1,
wherein the isolating first transistors are P-channel field effect transistors,
wherein the structure further includes a first bias voltage node electrically connected to a first source region in the first portion of the semiconductor body proximal to the first edge and first gates of the isolating first transistors, and
wherein the first bias voltage node is connected to receive a first positive supply voltage to maintain the isolating first transistors in the off state.

3. The structure of claim 2, further comprising a functional first transistor on the semiconductor body and separated from the first edge by the first portion.

4. The structure of claim 3, wherein a first drain region of an isolating first transistor in the first portion of the semiconductor body distal to the first edge is connectable by the functional first transistor to receive a first data signal with a first maximum voltage no greater than the first positive supply voltage.

5. The structure of claim 2,
wherein the isolation structure further includes isolating second transistors connected in series on a second portion of the semiconductor body adjacent to the second edge,
wherein the isolating second transistors are P-channel field effect transistors,
wherein the structure further includes a second bias voltage node connected to a second source region in the second portion of the semiconductor body proximal to the second edge and second gates of the isolating second transistors,
wherein the second bias voltage node is connected to receive a second positive supply voltage to maintain the isolating second transistors in the off state, and
wherein the second positive supply voltage is different from the first positive supply voltage.

6. The structure of claim 5, further comprising a functional second transistor on the semiconductor body and separated from the second edge by the second portion.

7. The structure of claim 6, wherein a second drain region of an isolating second transistor in the second portion of the semiconductor body distal to the second edge is connectable by the functional second transistor to receive a second data signal with a second maximum voltage no greater than the second positive supply voltage.

8. The structure of claim 1, further comprising:
a semiconductor substrate; and
a well region in the semiconductor substrate below the isolation structure.

9. The structure of claim 8, wherein the well region is a P-type well region.

10. The structure of claim 8, further comprising a well tap immediately adjacent to the well region, wherein the well tap is connected to receive a back gate bias voltage.

11. A structure comprising:
a semiconductor body; and
an isolation structure including:
a trench isolation region extending through the semiconductor body to an insulator layer, wherein the trench isolation region has a first edge and a second edge opposite the first edge; and
isolating first transistors connected in series on a first portion of the semiconductor body adjacent to the first edge, wherein the isolating first transistors are P-channel field effect transistors, wherein each isolating first transistor has a first source region and a first gate connected to a corresponding first bias voltage node to receive a first positive supply voltage to maintain the isolating first transistors in an off state.

12. The structure of claim 11, further comprising a functional first transistor on the semiconductor body and separated from the first edge by the first portion.

13. The structure of claim 12, wherein a first drain region of an isolating first transistor in the first portion of the semiconductor body distal to the first edge is connectable by the functional first transistor to receive a first data signal with a first maximum voltage no greater than the first positive supply voltage.

14. The structure of claim 11,
wherein the isolation structure further includes isolating second transistors connected in series on a second portion of the semiconductor body adjacent to the second edge,
wherein the isolating second transistors are P-channel field effect transistors,
wherein each isolating second transistor has a second source region and a second gate connected to a corresponding second bias voltage node to receive a second positive supply voltage to maintain the isolating second transistors in the off state, and
wherein the second positive supply voltage is different from the first positive supply voltage.

15. The structure of claim 14, further comprising a functional second transistor on the semiconductor body and separated from the second edge by the second portion.

16. The structure of claim 15, wherein a second drain region of an isolating second transistor in the second portion of the semiconductor body distal to the second edge is connectable by the functional second transistor to receive a second data signal with a second maximum voltage no greater than the second positive supply voltage.

17. The structure of claim 11, further comprising:
a semiconductor substrate; and
a well region in the semiconductor substrate below the isolation structure.

18. The structure of claim 17, wherein the well region is a P-type well region.

19. The structure of claim 17, further comprising a well tap immediately adjacent to the well region, wherein the well tap is connected to receive a back gate bias voltage.

20. A structure comprising:
a semiconductor body; and
an isolation structure including:
a trench isolation region extending through the semiconductor body to an insulator layer, wherein the trench isolation region has a first edge and a second edge opposite the first edge;
isolating first P-type field effect transistors (PFETs) connected in series on a first portion of the semiconductor body adjacent to the first edge, wherein at least a first source region in the first portion proximal to the first edge and first gates of the isolating first PFETs are connected to at least one first bias voltage node and wherein the at least one first bias voltage node is connected to receive a first positive supply voltage to maintain the isolating first PFETs in an off state; and
isolating second PFETs connected in series on a second portion of the semiconductor body adjacent to the second edge, wherein at least a second source region in the second portion proximal to the second edge and second gates of the isolating second PFETs are connected to at least one second bias voltage node, wherein the at least one second bias voltage node is connected to receive a second positive supply voltage to maintain the isolating second PFETs in the off state, and wherein the second positive supply voltage is different from the first positive supply voltage.
